(19) United States
(12) Patent Application Publication
(10) Pub. No.: US 2009/0220777 A1
(43) Pub. Date: Sep. 3, 2009

(54) Sputter Deposition Method, Sputter Deposition System and Chip

(76) Inventor: Martin Sporn, Villach (AT)

Correspondence Address: SLATER & MATSIL LLP, 17950 PRESTON ROAD, SUITE 1000, DALLAS, TX, 75252, US

(21) Appl. No.: 12/041,442

(22) Filed: Mar. 3, 2008

(51) Int. Cl. C23C 14/34; B32B 9/00

(52) U.S. Cl. 428/335; 204/192.15; 204/298.07

(57) ABSTRACT

According to an embodiment of the present invention, a sputter deposition method includes providing a sputter gas including krypton or xenon and accelerating ions of a plasma of the sputter gas towards a target material.

### TECHNICAL FIELD

Embodiments according to the present invention relate to sputter deposition methods, sputter deposition systems and chips, which may for instance be employed in the field of devices and objects based on thin film processes.

### BACKGROUND

In many fields of technology, thin film processes are utilized in the fabrication, refinement and finishing of a vast number of devices and further components. Examples come from the fields of electronic and electrical devices, integrated circuits, micromechanical devices, physical, chemical and biological sensors, optical components, mechanical components and many more fields of application. In many of these and other examples, a deposition of a film, for instance a thin film with a thickness of typically 100 μm or below is deposited by a deposition technique, such as a physical vapor deposition process (PVD). An important physical vapor deposition process is the sputter deposition technique, which is sometimes also referred to as sputtering.

As indicated earlier, sputter deposition processes are for instance employed in the field of fabricating integrated circuits, transistors, other electrical and electronic devices, micromechanical devices and sensors for physical, chemical or biological influences. Moreover, sputter deposition processes are employed in the field of optical systems, such as a finishing of optical lenses and other optical components as well as providing mechanical components with a layer to alter or improve mechanical or other properties of the component.

For instance in the field of electrical and electronic devices, a variety of issues limits the technical or economical applicability of the sputtering process, as several partly contradicting aspects have to be balanced in view of the desired outcome and results of the processes. Examples for these partly contradicting aspects are quality, process speed, reproducibility, costs and acceptable tolerances.

### BRIEF DESCRIPTION OF THE DRAWINGS

Embodiments according to the present invention will be described and explained with reference to the enclosed drawings and figures.

FIG. 1 shows a block diagram of a sputter deposition system according to an embodiment of the present invention;

FIG. 2 shows a cross section of a chip according to an embodiment of the present invention;

FIG. 3 shows a diagram illustrating a dependency of an equilibrium substrate temperature as a function of deposition rates for different sputter gases;

FIGS. 4a-4c schematically show cross sections of chips comprising films deposited according to a sputter deposition process employing argon as sputter gas;

FIGS. 4d-4f schematically show cross sections of chips comprising films deposited according to a sputter deposition method according to an embodiment of the present invention employing xenon as sputter gas;

FIGS. 5a and 5b illustrate binary collisions of an argon ion and a xenon ion with a gold atom;

FIG. 6 illustrates the maximum reflected ion energy for argon, krypton and xenon in a collision with gold; and

FIG. 7 illustrates an energy distribution of reflected argon, krypton and xenon ions in a collision with gold.

### DETAILED DESCRIPTION OF ILLUSTRATIVE EMBODIMENTS

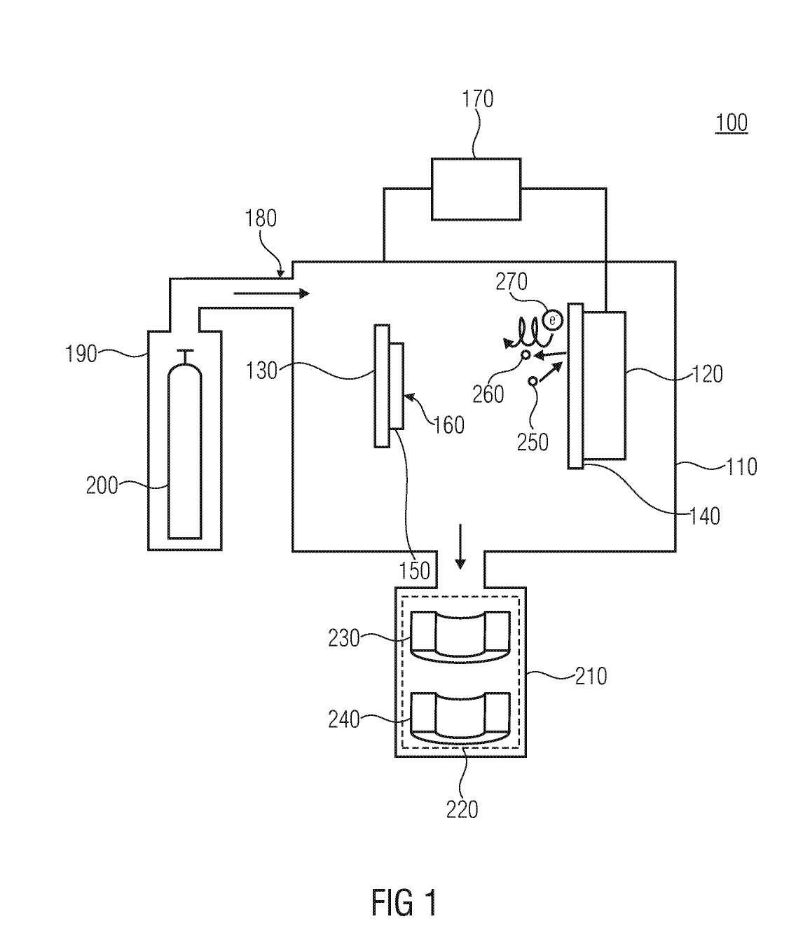

A sputter deposition system according to an embodiment of the present invention will be described below referring to FIGS. 1 to 7.

In the field of fabricating devices, such as integrated circuits, transistors, micromechanical devices, processors and other integrated circuits or elements, as well as in the field of manufacturing sensors and so-called integrated sensors, such as mechanical sensors, magnetoresistive sensors, pressure sensors, acceleration sensors as well as sensors for chemical, biological and other physical effects, thin film processes play an important role. Apart from implantation process steps generating or altering a doping of a semiconductor layer, patterning steps, milling steps and annealing process steps, the deposition of a monocrystalline, epitaxial, polycrystalline or amorphous layers of insulating or semiconducting material, metals and other materials represent frequently used process steps. Not only chemical vapor deposition processes (CVD), but physical vapor deposition processes (PVD), such as a sputter deposition process, which are sometimes also referred to as sputtering or sputtering processes, are often used.

Sputter deposition processes are generally attractive because they are capable of providing high deposition rates on the one hand and a good quality of the layers deposited on the other hand. At the same time, sputter deposition processes offer attractive economical aspects compared to other deposition processes, as, for instance, the vacuum requirements are significantly lower compared to MBE deposition systems (MBE=molecular beam epitaxy).

However, also when comparing different sputter deposition processes, a variety of issues limit the technical or economical applicability. These issues have to be balanced according to the specific application in mind as some of these aspects have contradicting tendencies. Some of these aspects are, as already mentioned, quality, process speed, reproducibility, costs and tolerances to name but a few.

Although a great variety of sputter deposition processes exist, the basic principle is generally the same in all these cases. A substrate on which a film or a coating is to be deposited on is placed along with a so-called target or target material in a process chamber or vacuum chamber that comprises a sufficiently specified or predetermined atmosphere, which is also referred to as sputter gas or sputter atmosphere. The sputter gas mainly comprises argon (Ar) as the central element of the sputter gas, but may also comprise further elements, such as oxygen (O₂), in the case of a reactive sputter deposition process.

As will be described in more detail in the context of FIG. 1, in the vacuum chamber or process chamber a plasma is ignited or generated in the sputter gas such that the ionized sputter gas atoms are accelerated towards the target material where the accelerated ions release target material atoms or target material particles upon impact.

Depending on the application in mind, a great variety of different target materials can be used in sputter deposition processes. Apart from semiconductors, insulating materials and metals, also combinations of these materials can be deposited on the substrate by sputter deposition processes. Examples for a combination of different materials or chemical elements represent alloys.

An alloy is a combination of at least two different chemical elements of which at least one is a metal. Important alloys in the fabrication of integrated circuits and other devices are, for instance, gold/tin (AuSn) and other low-melting alloys, that may be used to solder the resulting devices and sensors. For instance, the eutectic alloy of gold/tin has a melting temperature of about 280° C. However, other alloys may be employed comprising also non-metallic chemical elements, such as silicon (Si), oxygen (O), carbon (C) and other chemical elements. Alloys capable of being deposited by sputter deposition processes are not limited to eutectic alloys (see thermal evaporation processes). In principle all kinds of alloys should be depositable on a substrate using a sputter deposition process. In many cases, the film deposited on the substrate comprises the same or at least a very similar stoichiometric relation as the target material. Naturally, small deviations of typically less than ±10%, ±5% and ±2% may occur when comparing the stoichiometric relations of a deposited film and the target material.

However, significantly increased temperatures of the substrate may occur in a sputter process, when for instance growing gold/tin films. These high temperatures may lead to a melting of this low-melting alloy, which in turn might cause a separation of the different phases of the alloy and growth of large grains comprising a concentration of a dominant element of the alloy (e.g., Au or Sn in the case of AuSn). Moreover, a solution of components and films of underlying layers in the case of an intermediate product may occur, which might prevent soldering to the respective gold/tin film. Moreover, a noticeable noble gas incorporation of the used argon gas may take place in the case of a sputtered layer.

Apart from a reduction of the process speed by for instance reducing the sputtering rate by a factor of 2 to achieve the required or desirable grain structure, an active cooling by backside gas together with electrostatic clamping by employing an electrostatic chuck may be employed. However, the use of an electrostatic chuck might lead to a wafer breakage in the case of thin and very thin wafers as substrates having a thickness of a few 10 μm to 150 μm.

A reduction of the sputtering rate severely affects the throughput of the process and might lead to a dramatic increase in the costs of capital. With respect to the incorporated argon, it may for instance be released by an anneal process after the deposition. In other words, by increasing the temperature of the substrate, incorporated argon may be released. However, the annealing of the wafers after deposition to release the incorporated noble gas argon represents an additional process step, which slows down the overall process and/or generates additional costs and delays.

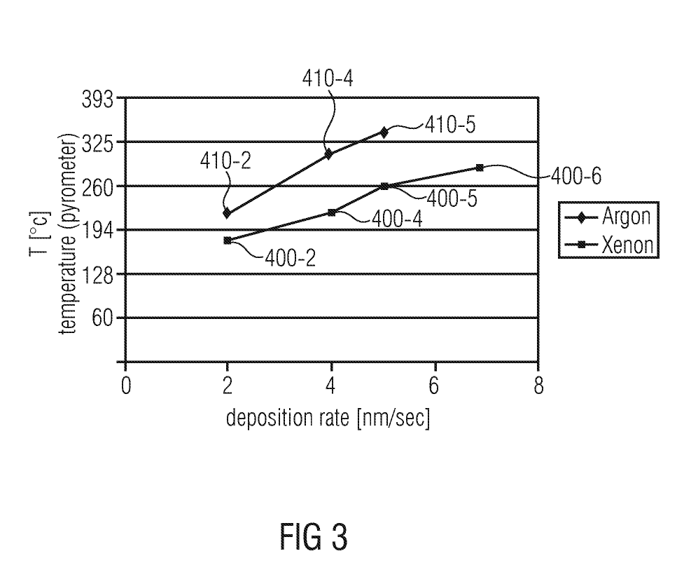

Embodiments according to the present invention are based on the finding that a reduction of the effects mentioned above may be reduced by replacing argon in the sputter gas with xenon (Xe) or krypton (Kr) as the key component of the sputter gas. The replacement of argon with xenon or krypton may lead to a reduction of the temperature of the substrate depending on the process parameters employed. Moreover, it may also lead to a finer grain structure, a faster process speed accompanied usually by improved cost efficiency, a finger grain structure of the deposited film on the substrate, an improved stability of the underlying layers or a combination of two or more of these effects depending on the concrete implementation of an embodiment according to the present invention and the process parameters. More details with respect to the mentioned effects will be explained and laid out in the context of FIGS. 3 to 7.

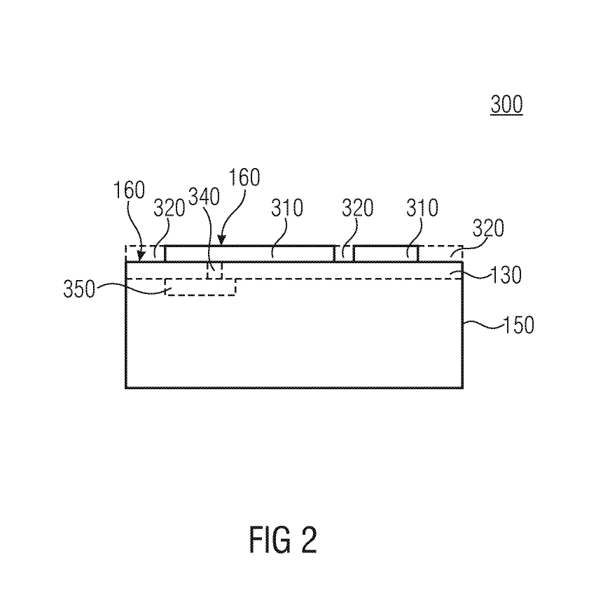

Before describing, with respect to FIG. 2, a substrate or a chip according to an embodiment of the present invention, first with respect to FIG. 1 a sputter deposition system according to an embodiment of the present invention along with a sputter deposition method according to the present invention will be described in more detail.

FIG. 1 shows a schematic representation of a sputter deposition system 100 according to an embodiment of the present invention. The sputter deposition system 100 comprises a vacuum chamber or process chamber 110, in which a target material holder 120 and a substrate holder 130 are arranged. The target material holder 120 is constructed such that a target material 140, which is also referred to as the target 140, is disposable on the target material holder 120 to facilitate a mechanical fixture or accommodation of the target 140. The substrate holder 130, which may for instance comprise a chuck, may optionally be constructed to accommodate a substrate 150 and to allow a mechanical or electrostatic fixture of the substrate 150, as will be outlined below.

Depending on the process parameters and other implementation details, the substrate holder 130 may optionally comprise an active cooling system, such as a Peltier element or backside admission of gas with typical pressures of several mbar and below. Due to the pressure in the process chamber during the deposition, which is in many cases smaller, the substrate holder 130 may require in these cases a mechanical or electrostatic fixture. However, in the case of very thin substrates (e.g., with thicknesses of less than about 100 μm) the mechanical stress, which the substrate is subjected to, might lead to higher failure rate due to cracks and other damages of the wafer.

The substrate 150 may be a monocrystalline or a polycrystalline substrate made out of an insulating (e.g., sapphire, SiO₂, glass), semiconducting (Si), metallic or conducting material. Its shape may be circular or oval, rectangular, quadratic or polygonal. A circular substrate is often referred to as a wafer. The thickness of the substrate may for instance vary between a few 10 μm and several millimeters (e.g., about 4 mm). But a substrate may also comprise a different form, e.g., a hollow sphere-like shape, as also optical components like lenses for a pair of glasses may be used. As the following description will mainly focus on electronic devices, many substrates are silicon wafers in these applications so that the terms substrate and wafer can be used to some extent synonymously. However, one should bear in mind, that embodiments according to the present invention are by far not limited to these substrates of the semiconductor industry, but may also be employed in many other fields of technology. Hence, the term substrate refers in the framework of this description to a general object on which a film is to be deposited.

The mechanical accommodation of both, the substrate 150 on the substrate holder 130 and the target material 140 on the target material holder 120, can be accomplished in a large variety of ways, for instance, including the options of a mechanical fixture, an electrostatic fixture, a magnetic fixture or a combination of these. However, depending on the concrete implementation and the geometrical arrangement of the target material 140 and the substrate 150 with respect to each other, the previously described fixtures are optional as, for instance, the substrate 150 may simply be put down on the substrate holder 130 and be located there due to a geometrical shape of the substrate holder 130 and simply by its own weight.

The target material 140 is in the embodiment of a sputter deposition system as shown in FIG. 1 a plain disk-like shaped. In this case, depending on other implementational details and further considerations concerning the sputter deposition system 100, it might be advisable to arrange a main surface 160 of the substrate 150 vice versa to a corresponding main surface of the target material 140. The main surface 160 of the substrate is the surface on which the film is to be deposited. Hence, the main surface 160 may also be the backside of a wafer or substrate, the spherical surface of a lens or any other surface on which a film is to be deposited.

The target material holder 120 may optionally comprise a magnet oriented to generate a magnetic field inside the process chamber 110, which is essentially perpendicular with respect to a surface of the target material 140. As a consequence, free electrons move in orbit-like trajectories due to Lorentz forces acting upon them so that the length of the trajectory of the free electrons is increased compared to a target material holder without a magnet. A configuration, as shown in FIG. 1, with a magnet is usually referred to as a magnetron sputter deposition configuration.

The sputter deposition system 100 shown in FIG. 1 according to an embodiment of the present invention may further comprise a transporter as an optional component adapted to transport the substrate 150 onto the substrate holder 130. Such a transporter, which is not shown in FIG. 1 for the sake of simplicity, may for instance comprise a vacuum handling or transfer system.

The embodiment according to the present invention shown in FIG. 1 furthermore comprises a plasma generator 170, which is in this case coupled to the process chamber 110 and the target material holder 120. In this case, the substrate holder 130 may be electrically insulated from the process chamber and other components. This arrangement is also referred to as an electrically floating configuration.

However, in different sputter deposition systems according to embodiments of the present invention the plasma generator 170 may also be coupled to the substrate holder 130 or a further optional electrode, which is not shown in FIG. 1. Depending on the concrete implementational details of the sputter deposition system 100, the target material holder 120 and the substrate holder 130 may optionally be adapted to provide an electrical contact of the substrate 150 and/or of the target material 140 to the plasma generator 170, unless the substrate holder 130 is electrically insulated from its environment (e.g., the process chamber 110). This configuration might lead to a non-negligible current over the freshly deposited film under some conditions.

The arrangement with an additional electrode inside the process chamber 110, which is coupled to the plasma generator 170, is sometimes also referred to as a triode configuration, for instance, when the substrate holder 130 and optionally the substrate 150 are coupled to a referent potential (e.g. ground).

The plasma generator 170 may for instance comprise a voltage source capable of providing a DC voltage, an AC voltage or a combination of both voltages to the target material holder 120. In the case of a DC voltage applied to the target material holder 120 as shown in FIG. 1, the sputtering process is referred to as a DC sputter deposition process, while in the case of an AC voltage, the sputtering process is referred to as a RF sputter deposition process (RF=radio frequency).

In the case of a DC voltage source, the cathode of the voltage source is typically coupled to the target material holder 120 while the anode is coupled to the substrate holder 130, the additional electrode not shown in FIG. 1 or the process chamber 110 so that positively charged ions will be accelerated towards to the target material 140 while freely moving electrons will be accelerated away from the target material 140. As a consequence, due to the optional magnet of the target holder 120, which is also referred to as the target holder magnet, electrons generated in the vicinity of the target material 140 will move along spiral-like orbits at least in the vicinity of the target holder 120 while being accelerated away from the target material 140.

The process chamber 110 furthermore comprises a sputter gas inlet 180 mechanically coupled to the process chamber 110 to allow the sputter gas to be provided to the inside of the process chamber 110. A sputter gas supply system 190 is mechanically coupled to the sputter gas inlet to supply the sputter deposition system 100 with the sputter gas. The sputter gas supply system 190 is constructed to provide xenon or krypton as the sputter gas to the process chamber 110.

However, as previously outlined, the sputter gas may also comprise further chemical elements depending on the desired processes. Hence, the sputter gas supply system may also be capable of providing oxygen or other process gases. The sputter gas supply system 190 may, for instance, comprise one or more gas cylinders 200 for xenon and/or krypton and optionally for the further process gases, if desired or required by the process in mind. The use of xenon or krypton may, for instance, require a different gas supply compared to a corresponding gas supply system for deposition modules employing argon as the sputter gas. Moreover, depending on details of the implementation, one or more sputter gas supply systems 190 for different sputter gases may be installed on a deposition module on the same tool. Apart from the gas cylinder 200, also the sputter gas supply system 190 may further comprise valves, pressure control systems and further components, as mentioned above.

The gas inlet 180 may further comprise components to control, to regulate and/or to make the gas flow inside the process chamber 110 switchable. Hence, the gas inlet 180 may comprise switchable valves, controllable valves (e.g., butterfly valves, plate valve), flow controllers and other components (e.g., dryer, particle filters).

The sputter deposition system 100 furthermore comprises a pumping system 210, which is coupled to the process chamber 110 and capable of pumping the sputter gas out of the process chamber 110. Naturally, depending on the overall design of the sputter deposition system 100 according to an embodiment of the present invention, the pumping system 210 may also be capable of extracting other gases and atmospheres present in the process chamber 110.

The pumping system 210 shown in FIG. 1 comprises a cryo pump 220 with a first cold surface 230 and a second cold surface 240. During operation of the cryo pump 220, the first cold surface 230 and the second cold surface 240 are cooled down to a first temperature and a second temperature, respectively, such that gas molecules of the sputter gas or other gas molecules in the process chamber 110 can be absorbed or adsorbed on the cold surfaces 230, 240 depending on the type of gas molecule. The cold surfaces 230, 240 may for instance be formed as baffles to increase their surface area compared to a more compact design to allow a greater number of molecules to be adsorbed.

In some embodiments the cryo pump 220 may comprise exactly two stages comprising to different cold surfaces 230, 240, which are operated at different temperatures. Naturally, each of the exactly two cold surfaces or each of the further cold surfaces may comprise one or more partial surfaces to enlarge the actual area of the respective surfaces 230, 240. In other words, the cold surfaces may be “distributed” among several partial surfaces.

Naturally, the pumping system 210 may also comprise a further pump not shown in FIG. 1 to generate a low vacuum or a fore-vacuum prior to turning on the cryo pump 220. Such a further pump may for instance be a rotary vane pump or a Roots pump.

In operation, the sputter deposition system is brought down to or maintained at a background pressure by the pumping system 210, which is suitable for the quality and the further demands mentioned above in view of the quality to be achieved. For instance, the process chamber 110 may be brought to a background pressure before providing the sputter gas to the process chamber 110 of 10-5 mbar by the pumping system 210. With the substrate 150 in place on the substrate holder 130, the sputter gas comprising krypton or xenon is provided by the sputter gas supply system 190 and the inlet 180 to the process chamber 110. At the same time, the pumping system 210 extracts the sputter gas at a rate such that a constant pressure level of the sputter gas is achieved inside the process chamber, while the sputter gas is pumped through the process chamber in flow from the sputter gas supply system 190 via the gas inlet 180 and the process chamber 110 to the pumping system 210. Naturally, the gas supply can also be controlled to generate the desired pressure inside the process chamber 110. This configuration is also referred to as a gasflow sputtering configuration.

After reaching the desired pressure level, for instance a pressure of 2.0·10-3 mbar or below, a plasma is generated inside the process chamber by the plasma generator 170. For instance, by applying a DC voltage between the target material holder 120 and the process chamber 110, a plasma is ignited in the sputtering gas, which comprises positively charged krypton ions Kr+ or positively charged xenon ion Xe+ along with a number of free electrons e−. Depending on the polarity of the DC voltage, the positively charged ions are accelerated towards the target material 140, as indicated in FIG. 1 by an exemplary ion 250. Upon impact of the ion 250 on the surface of the target material 140, an atom 260 or a cluster of the target material is ejected by the target 140.

Due to the negative charge of the free electrons, the electrons are accelerated in the opposite direction compared to the acceleration direction of the ions 250, as schematically illustrated by a single electron 270 in FIG. 1. Due to the magnet comprised in the target material holder 120 according to the magnetron sputtering configuration, the free electrons (e.g., electron 270) move in spiral-like trajectories. On their way, the electrons collide with molecules of the sputter gas leading to an ionization of the respective molecules leaving one or more free electrons so that the plasma ignited in the process chamber 110 will be upheld simply by providing the DC voltage by the plasma generator 170.

Atoms or particles of the target material emitted by the target material 140 due to the impact of the ions of the plasma will move through the process chamber and condensate on the main surface 160 of the substrate 150. As a consequence, on the main surface 160 of the substrate 150 a film of the target material is deposited comprising approximately the stoichiometric relation of the target material 140. Due to the condensation energy of the target material atoms or clusters upon impact on the substrate, energy is introduced to the substrate in the form of heat, which may lead to a rising substrate temperature. In the case of lower pressures of the process gas (e.g., below 4.0·10-3 mbar), the dominating mechanism for transporting heat from the substrate is radiation, since the effect of convection is comparably low at low pressures. The equilibrium temperature of the substrate during the deposition is hence influenced by the condensation energy of the incoming target material and the loss of energy due to radiation (e.g., infrared radiation and other spectral contributions).

Moreover, atoms and particles of the target material emitted by the target 140 will also reach other parts of the process chamber, such as the substrate holder 130. Due to the pressure of the sputter gas in the process chamber 110, atoms and particles of the target material may even reach the backside of the substrate holder 130 due to scattering processes with molecules of the sputtering gas. Depending on the mean free path between scattering incidents, the number of scattering events of an average target material atom or cluster will be different. Among other parameters, the pressure of the process or sputter gas determines the mean free path.

Typical values of voltages applied by the plasma generator 170, resulting currents, distances between the target material 140 and the substrate 150 as well as further operational parameters, such as the pressure of the sputter gas and the background pressure of the process chamber 110, depend on the desired quality, grain size, deposition rate and other process-related and sputter deposition system-related parameters. The distance between the target material 140 and the substrate 150 may for instance be chosen to be approximately of the order of the mean free path in the sputter gas.

For instance, with a distance between the target material 140 and the substrate 150 of about 10 mm to about 80 mm, a typical DC voltage applied by the plasma generator 170 is in the range of about 100 V to about 1 kV (e.g., about 500 V) and as a process pressure of the sputter gas xenon of 2.0·10-4 mbar to 1.0·10-1 mbar. Higher pressures of the process gas generally tend to decrease the uniformity (i.e., increasing the non-uniformity) of the deposited films (e.g., leading to a less hill-like cross section of the deposited film) and may also negatively affect the deposition rate. However, different parameters may also be used depending on the circumstances, the concrete implementation of the sputter deposition system and the quality, deposition rate and other factors to be achieved. In other words, the plasma might be operated at a different current-to-voltage ratio when using xenon or krypton compared to argon.

A sputter deposition system 100 according to an embodiment of the present invention might also differ from its argon-based counterpart compared to the cryo pump 220 used. In the case of the cryo pump 220 comprising at least two stages with at least one cold surface in each of the stages, the first cold surface 230 of the first stage is often operated at temperatures above about 70 K, about 75K or at temperatures of about 80 K or above compared to a first stage of the cryo pump for a sputter deposition system based on argon, which is often operated at about 65 K. The second cold surface 240 of the second stage of the cryo pump 220 may for instance be operated at temperatures below about 50 K, about 30 K or about 20 K, such as about 14 K. While the second cold surface 240 of the second stage of the cryo pump 220 is mainly provided for capturing the sputter gas xenon or krypton, the first cold surface of the first stage of the cryo pump 220 is mainly provided for further components and contaminations of the sputter gas, such as oxygen, water vapor (H₂O), nitrogen (N₂) and other gases.

In other words, in the case of employing xenon and krypton, it might be advisable to operate the first cold surface 230 at a temperature well above about 65 K in order to reduce the amount of captured xenon or krypton or to prevent the capture of these gases completely. Comparing a cryo pump 220 employed in a pumping system 210 of a sputter deposition system 100 according to an embodiment of the present invention, the cryo pump 220 might be operated at a different temperature. This may for instance be achieved by a non-standard software configuration or accordingly adjusted parameters.

Naturally, also other pumping systems 210 may be employed in sputter deposition systems 100 according to an embodiment of the present invention. An example for such a pumping system is for instance an incorporation of a turbomolecular pump optionally along with a pump for a fore-vacuum or a low vacuum. However, also other types of pumps may be employed.

However, sputter deposition systems 100 according to embodiments of the present invention are not limited to the precise implementational details as shown in FIG. 1. Apart from the already mentioned variations concerning the pumping system 210, also the sputter system itself comprising the substrate holder, the target material holder, the target material as well as the plasma generator 170 can be altered. The sputter deposition system 100 shown in FIG. 1 is a plain cathode magnetron sputter deposition system because the target material holder 120 comprises a magnet generating the previously described magnetic field to force the free electrons on spiral-like orbits on the one hand and because the target material 140 is manufactured as a plain disk, which is attached to the target material holder 120, on the other hand. Moreover, the sputter deposition system 100 is a DC sputter deposition system as the plasma generator 170 comprises a DC voltage source as previously described.

As mentioned earlier, the magnet comprises, in the target material holder 120, an optional component and is not required to be implemented. In the case of the magnet not being implemented, the free electrons are not forced by the Lorenz force on orbit-like orbits, which reduces the probability of sputter gas molecules being ionized by a free electron.

Moreover, the target material 140 can be implemented as a hollow tube. A respective sputter deposition system 100 is then referred to as a hollow cathode sputter deposition system.

Moreover, a plasma generator 170 may for instance comprise an AC voltage source instead of a DC voltage source. The resulting so-called RF sputter deposition system (RF=radio frequency) might for instance be favorable in the case of an insulating target material 140.

Naturally, the previously described options can also be combined, for instance, to yield a RF hollow cathode magnetron sputter deposition system, a DC hollow cathode magnetron sputter deposition system or further combinations.

Before describing further embodiments according to the present invention, it seems to be appropriate to point to the fact that in the present description objects and structures with the same or similar properties or features will be referred to with the same or similar reference signs. In order to keep the description as short as possible, it should be noted that parts of the description referring to structures and objects with the same or similar functional or other properties and features can be exchanged or supplemented with respect to each other, unless noted otherwise. As a consequence, unnecessary repetitions can be avoided.

FIG. 2 shows a cross section of a chip 300 according to an embodiment of the present invention comprising a substrate 150. As described in the context of FIG. 1, the substrate 150 comprises a main surface 160 on top of which a film 310 of a target material is deposited using a sputter deposition method according to an embodiment of the present invention. The film covers, due to an optional previous patterning and milling step, a structure such that the film does not cover the complete main surface 160 of the substrate 150. However, the film 310 covers at least portions of a plane parallel to the main surface 160 of the substrate 150. Very often the main surface 160 is the actual surface of the substrate, on which the film is to be deposited on, but may in principle also be buried under further films, layers and structures, when for instance the substrate has been further processed.

However, the deposited film is not required to be patterned and milled. It may also cover the whole main surface 160 of the respective substrate. This may, for instance, be the case when the main surface 160, on which the film is to be deposited, is the backside of the substrate to form a body or source contact of a vertical transistor (e.g. LDMOS=laterally double-diffused metal oxide semiconductor), to name only one possible example.

The film 310 may be a thin film with a thickness ranging from fractions of a nanometer to several micrometers or a thick film with a thickness of more than a few micrometers up to several 100 micrometers. Moreover, the film 310 may comprise any target material as mentioned before. In other words, the film 310 may, for instance, comprise metals, alloys, semiconducting materials, insulating materials or a combination of any of the previously mentioned.

The chip 300 may optionally further comprise one or more further films 320, which fill up the spaces between the structure of the film 310. The further film 320 may for instance be an insulating film in the case that the film 310 is a metallic, semiconducting or other conducting film. In the situation shown in FIG. 2, the further film 320 comprises the same thickness as the film 310 so that the film 310 together with the further film 320 provides a new main surface 160′, which is parallel to the main surface 160.

As this example has shown, the substrate 150 may comprise further films and structures. In other words, the substrate 150 may be a new substrate as well as an intermediate product or a finished product.

To illustrate this further, the cross section of FIG. 2 of the chip 300 shows an insulating film 330 underneath the main surface 160 that comprises a vertically conducting lead 340, which is also referred to as a via 340. The via 340 connects the film 310 with a structure 350 lying underneath the insulating film 330. However, as indicated earlier, the exemplary structure of the chip 300 underneath the main surface 160 as well as the structure of the film 310 and the further film 320 on the main surface 160 only serve to illustrate that the substrate 150 may comprise further structures depending on the state of the fabrication process.

The film 310 deposited using a sputter deposition method according to an embodiment of the present invention, for instance, employing a sputter deposition system according to an embodiment of the present invention, may comprise contaminations not present in the target 140 of the sputter deposition system 100. An incorporation of the sputter gas may occur leading to a detectible concentration of the sputter gas krypton or xenon. In other words, utilizing krypton as the sputter gas might lead to a detectible concentration of krypton in the film 310. The same may also occur in the case of xenon as the sputter gas. Hence, depending on the parameters employed during the deposition of the respective film 310, the method employed in depositing the film 310 may be detectible by analyzing the composition of the film 310.

Depending on many parameters, a concentration of the sputter gas in the film 310 may vary in wide ranges. Starting from concentrations which represents merely traces of 100 ppm (parts per million) all the way down to less than 1 ppb (parts per billion). But the concentration may also be higher leading to a level which might be considered a contamination. Depending on the parameters and circumstances involved during the deposition of the film 310, the concentration might reach levels of several percent up to 5 or 10%. Hence, the concentration of the sputter gas xenon or krypton might be in the range having a lower limit between any value of approximately 1 ppb and 100 ppm and an upper limit of any value in the range of approximately 100 ppm to 10%.

As the sputter gas is a noble gas according to an embodiment of the present invention, the possibilities of chemical reactions of the target material in the film 310 with the xenon or krypton are limited, if any chemical reaction takes place at all. As a consequence, the xenon or krypton of the sputter gas will in most cases simply be incorporated instead of establishing chemical bonds to the target material or other elements, for instance, from lower lying structures and films.

As mentioned earlier, the temperature of the substrate 150 employing a sputter deposition method according to an embodiment of the present invention is compared to a sputter deposition process involving argon. To illustrate this further, FIG. 3 shows a comparison of a temperature value T of the substrate 150 measured by the use of a pyrometer as a function of the deposition rate of the target material on the substrate 150 for argon (Ar) and xenon (Xe). FIG. 3 shows an overall number of seven data points representing the wafer temperature as the maximum temperature during the process corresponding to four deposition rates for the use of argon and xenon as sputter gas. The data points 400-2, 400-4, 400-5 and 400-6 corresponds to measured temperatures for xenon as the sputter gas according to embodiments of the present invention and deposition rates of 2 nm/s, 4 nm/s, 5 nm/s and 6 nm/s, respectively. Moreover, FIG. 3 shows three data points 410-2, 410-4 and 410-5 corresponding to temperature values of the substrate measured during a process using argon as the sputter gas for deposition rates of 2 nm/s, 4 nm/s and 5 nm/s, respectively.

As direct comparisons of the data points 400, 410 corresponding to the same deposition rates illustrate, lower wafer temperatures at the same deposition rates can be achieved when the target material (AuSn) are sputtered with xenon according to an embodiment of the present invention compared to the use of argon as the sputter gas. Moreover, it was possible to roughly double the deposition rate from 2 nm/s when using argon to 4 nm/s when using xenon while maintaining essentially the same or at least a comparable measured maximum substrate temperature of around 220° C. This temperature represents a temperature leading to a good quality of the deposited gold/tin films during the tests, since it is still lower than the meting temperature of about 280° C. of the eutectic alloy AuSn used.

However, it should be noted that this temperature is not only a material-specific and application-specific temperature, but depends also on further equipment-specific and process-specific aspects and parameters. Some of these aspects and parameters comprise, for instance, the special geometry of the sputter deposition system including depositions of the substrate 150 with respect to the target 140, the structure of the substrate 150 and further parameters.

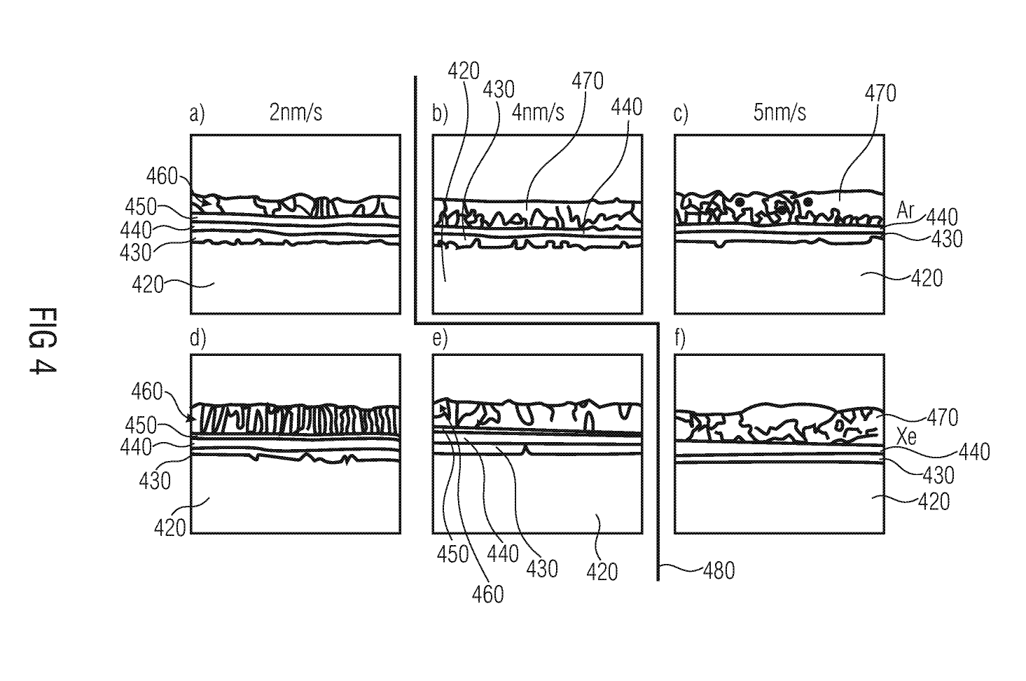

To illustrate this further, FIGS. 4a to 4f show six schematic representations of focused ion beam images (FIB) of cross sections of gold/tin layers (eutectic alloy) sputtered with argon and xenon on a substrate comprising several additional films and layers. The six schematic cross sections shown in FIGS. 4a to 4f correspond to the six data points 400-2, 400-4, 400-5, 410-2, 410-4 and 410-5 shown in FIG. 3. In other words, the temperature data of these six data points shown in FIG. 3 are taken from the same wafers as the cross sections shown in FIGS. 4a to 4f.

The test wafers of which cross sections are shown in FIGS. 4a to 4f after a deposition of a gold/tin film (AuSn, eutectic alloy) are based on similar wafers prior to the deposition of the gold/tin film (AuSn). The resulting film generated during the final deposition of gold/tin is in all six images of FIGS. 4a-4f the upper layer.

The basic structure of the substrate prior to the deposition will be explained in more detail with respect to the cross section shown in FIG. 4a corresponding to a deposition of gold/tin with a deposition rate of 2 nm/s using argon as the sputter gas. The image shown in FIG. 4a, hence, corresponds to the data point 410-2 of FIG. 3.

The waver itself is a silicon wafer 420 (Si wafer), on top of which an aluminum film 430 (Al), a titanium film 440 (Ti) and a thin nickel film 450 (Ni) was deposited prior to depositing a gold/tin film 460. While the silicon wafer 420, the aluminum film 430, the titanium film 440 and the nickel film 450 each comprise essentially only one chemical element (apart from possible contaminations), the film 460 of gold/tin comprises an (eutectic) alloy of the two metals gold (Au) and tin (Sn). As a consequence, in a focused ion beam image (FIB) as well as an in a scanning electron microscope picture (SEM), different phases of the alloy comprising different concentrations of the two components of the alloy are visible as shades due to the different masses of their nuclei. While gold (Au) has a relative atomic weight of approximately 196.97 u, tin has a relative atomic weight of approximately 118.71 u, wherein u is the atomic mass unit and is approximately equal to u=1.6605655·10-27 kg. This essentially means that the cross sections shown in FIGS. 4a to 4f are capable of disclosing the distribution of at least two phases in the alloy. In FIG. 4a, this is indicated by the vertical, diagonal and horizontal lines inside film 460. The main phases of the film 460 is a gold-rich phase with a ratio of roughly 5:1 with respect to the concentration of gold (Au) and tin (Sn), which is also referred to as “zeta-phase” (ζ-phase), and a phase with roughly the same concentration of gold and tin (i.e. approximately 1:1), which is also referred to as the delta-phase (δ-phase).

As previously explained, the six cross sections shown in FIGS. 4a to 4f are based on essentially the same wafer prior to the deposition of the gold/tin film 460. Hence, also FIGS. 4b to 4f all show the underlying silicon wafer 420, the aluminum film 430 on top of the silicon wafer 420 and the titanium film (440) on top of the aluminum film 430.

However, by doubling the deposition rate from 2 nm/s to 4 nm/s when moving from FIG. 4a to 4b in the case of using argon as the sputter gas for the gold/tin film deposited on top of the nickel layer, the temperature of the substrate rises significantly above 260° C. as data point 410-4 in FIG. 3 shows. This causes the nickel layer 450 shown in FIG. 4a to start to dissolve and the gold-rich phase and the delta-phase to separate even further compared to the internal structure of the gold/tin film 460 shown in FIG. 4a. As a consequence, the cross section of FIG. 4b does not show the thin nickel film 450 anymore and a third phase starts to evolve in a film 470, which is similar to the delta-phase, but in which the gold atoms (Au) are at least partly replaced by nickel atoms (Ni) (also referred to as nickel-comprising phase). The gold-rich phase (zeta-phase) tends to float on top of the other phases inside film 470. By depositing the gold/tin alloy by the use of argon at a deposition rate of 4 nm/s, the film 470 was generated comprising not only gold and tin but also the nickel of a nickel film 450.

By even further increasing the deposition rate to 5 nm/s in the case of the use of argon as the sputter gas, the temperature of the substrate exceeds the 325° C. line as the data point 410-5 in FIG. 3 shows and hence the melting temperature of AuSn. Accordingly, the corresponding cross sections shown in FIG. 4c shows an even more dissolved film 470 taking the place of the deposited gold/tin film and the nickel film. FIG. 4c shows furthermore that the dissolved metals in film 470 start to form spheres of different components and the nickel-comprising phase inside film 470.

FIGS. 4d to 4f show results of tests based on the same wafer with the same aluminum, titanium and nickel films 420, 430, 440 on top of which a gold/tin film is deposited by using a sputter deposition method according to an embodiment of the present invention employing xenon as sputter gas. The arrangements of the FIGS. 4d to 4f reflect the deposition rates on which the sputtering of the gold/tin films 460 was based.

FIG. 4d shows a very fine columnar structure of the different phases of gold and tin of the gold/tin film 460 deposited on top of the nickel film 450. The cross section of FIG. 4d corresponds to a deposition rate of 2 nm/s and to a temperature of less than 195° C. as the corresponding data point 400-2 in FIG. 3 shows. A direct comparison of the gold/tin films 460 shown in FIGS. 4a and 4d, hence, illustrates that by employing xenon as the sputter gas according to an embodiment of the present invention a significantly finer grain structure or phase structure of the gold/tin alloy is achievable.

Essentially doubling the deposition rate from 2 nm/s to 4 nm/s results in a cross section as shown in FIG. 4e. As the data point 400-4 corresponding to the cross section shown in FIG. 4e illustrates, the wafer temperature during the deposition of the gold/tin film is in the range of approximately 220° C. Not only the temperature of the substrate during the deposition of the gold/tin film 460 is comparable to that of the wafer shown in FIG. 4a corresponding to data point 410-2, but also the microstructure of the resulting gold/tin film 460 is comparable to that of the wafer shown in FIG. 4a.

By increasing the deposition rate from 4 nm/s to 5 nm/s for depositing the gold/tin film using a sputter deposition according to an embodiment of the present invention, the nickel film 450 will once again start to dissolve so that the resulting film 470 does not only comprise gold and tin but also dissolved nickel of the underlying structure. Hence, the microstructure of the film 470 is more comparable to that of the films 470 shown in FIGS. 4b and 4c than to that of the film 460 shown in FIGS. 4a and 4e.

To summarize, a finer grain structure evolves when sputtering with xenon according to a sputter deposition method according to an embodiment of the present invention at the same deposition rate as with argon. This allows a colder process, a faster process or a process employing a combination of both.

By employing xenon according to an embodiment of the present invention, the process speed, significantly influenced by the deposition rate (essentially the process speed), can be doubled without sacrificing the quality of the microstructure of the resulting film 460. Essentially the same grain size of the phases of the alloy of film 460 is achievable, as a comparison of FIGS. 4e and 4a as well as the corresponding data points 400-4 and 410-2 of the wafer temperature has shown.

Moreover, the process is more stable against a solution of components of underlying layers which are seen as spherical phases in the cross sections of FIG. 4. The transition of a microstructure from columnar grains, especially visible in FIG. 4d but also present in FIGS. 4a and 4e to dissolve spherical phases as shown in FIGS. 4b, 4c and 4f is indicated by a line 480 in FIG. 4. As a comparison with FIG. 3 shows, this occurs at higher deposition rates for xenon compared to argon. An evaluation of the spherical phases on the right side of line 480 shows that the grains or phases generate larger grains and are dissolved similar to a soldering processes separating the phases of an alloy.

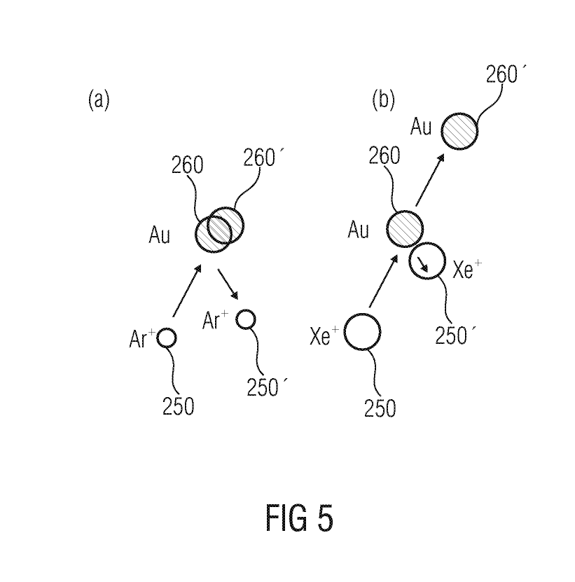

The effect of sputtering and sputter deposition methods is based on a binary collision between the projectile gas or sputter gas and target atoms of the target material. The projectile gas transfers energy and momentum to the target atoms and decelerates. FIGS. 5a and 5b illustrate the situation in the case of gold (Au) as target atoms and argon (Ar) as projectile or sputter gas in FIG. 5a and xenon (Xe) as projectile or sputter gas in FIG. 5b.

FIG. 5a shows the situation in the framework of the binary collision model for an argon ion 250 (Ar+) heading towards a gold atom 260 (Au). In the collision, energy and momentum are transferred from the argon ion 250 to the gold atom 260 so that the argon 250 gets partly reflected in the collision with the gold atom 260. This is illustrated in FIG. 5a by an argon ion 250′ moving away from a slightly moved gold atom 260′.

The argon ion 250′ moves after the collision with the gold atom 260 in the general direction of the substrate. As a consequence, the scattered argon ion 250′ impinges with a significant energy on the wafer surface, which can lead to an energy transfer of the argon ion 250′ onto the substrate. As argon is a noble gas and will hence not participate significantly in a chemical reaction, the argon may be incorporated into the growing film on the substrate without building chemical bonds leading to molecules. However, due to the incorporation of the argon, the kinetic energy of the argon ion 250′ will be input to the growing film leading to a heating of the film and the substrate.

FIG. 5b shows a similar situation in the case of using xenon as the sputter gas according to an embodiment of the present invention. The xenon ion 250 (Xe+) moves towards the gold atom 260. Due to the collision of the xenon ion 250 and the gold atom 260, the xenon ion 250′ is decelerated as shown in FIG. 5b in form of a reflected xenon ion 250′. Due to the energy and momentum transfer from the xenon ion 250 onto the gold atom 260, the gold atom 260 is accelerated as shown in FIG. 5b by the displaced gold atom 260′. Hence, by using xenon as the sputter gas according to an embodiment of the present invention, the energy of the xenon ion 250 is transferred to the gold atoms 260 so that the bombardment of the substrate with high energetic particles is reduced if a bombardment takes place at all.

In other words, argon is used as a standard process gas or sputter gas in widespread applications like sputtering of aluminum (Al). Gold and tin, however, are heavy atoms in comparison to argon. While gold has a molecular weight of 196.97 u and tin (Sn) has a molecular weight of 118.71 u, argon has a molecular weight of only 39.95 u. Hence, the mass ratio of gold to argon is approximately 4.9 and that of tin to argon approximately 3.0. Due to this mass ratio, argon is very likely to be reflected with a significant kinetic energy by the target atoms in the case of gold and tin. Hence, as outlined before, this kinetic energy can lead to a heat transfer to the growing film on the substrate and therefore lead to an increased temperature of the substrate during the deposition process.

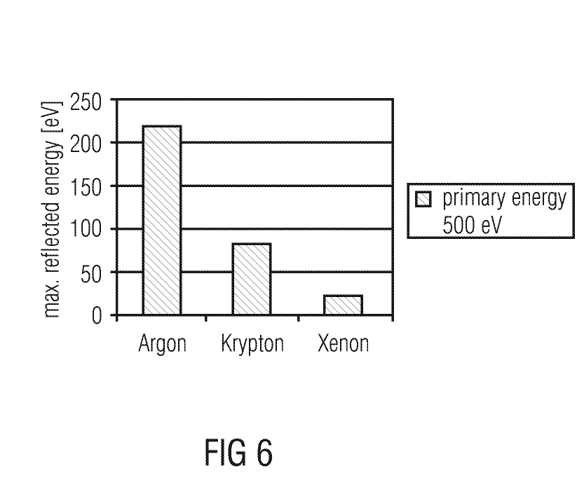

To illustrate this further, FIG. 6 shows the maximum reflected energy of argon, krypton and xenon atoms in an elastic collision with gold at an incident energy or primary energy of 500 eV. While the maximum energy of reflected argon is in this scenario approximately 220 eV, the maximum energy of the reflected atoms after an elastic collision between krypton and gold is approximately 80 eV, which is roughly speaking approximately one third of the maximum reflected energy of argon or half an order magnitude smaller than the value for argon. In comparison, the maximum reflected energy of xenon is only approximately 25 eV and, hence, approximately a full order of magnitude (a factor of 10) smaller than the maximum reflected energy of argon.

The reflected projectile ions are very likely to impinge on the wafer or substrate contributing to heating the growing film in addition to the condensation energy and the kinetic energy of the deposited target material, for instance, gold and tin atoms. The energy of the reflected projectile is reduced to less than 50 eV when using xenon according to an embodiment of the present invention instead of argon as FIG. 6 has shown. This is due to the fact that xenon has a comparable mass to gold and tin and hence transfers a much larger amount of its energy and momentum so that it is decelerated at the impact at the target surface.

Xenon has a molecular weight of 131.29 u so that the mass ratio of gold to xenon is approximately 1.5 and that of tin to xenon of approximately 0.9. As krypton has a molecular weight of approximately 83.80 u, the mass ratio of gold to krypton is approximately 2.4 and that of tin to krypton approximately 1.4. Although based on the mass ratios alone, xenon offers a more attractive mass ratio than krypton, krypton might be a more favorable sputter gas according to an embodiment of the present invention in some applications. Apart from further process-related parameters, krypton might for instance be more cheaply available than xenon.

Due to these significantly higher atomic weights of krypton and xenon, sputter deposition methods and sputter deposition systems according to embodiments of the present invention can be fruitfully applied in the case of depositing target material comprising heavier elements. Based on mass ratios of 0.7 and above (e.g., approximately 1) of the target material or at least one component of the target material with respect to the atomic weight of the sputter gas, krypton (molecular weight of 83.30 u) as the sputter gas might, for instance, be interesting for target materials comprising at least one component having 55 u and 85 u and above, respectively. Xenon having a molecular weight of 131.29 u might hence be interesting for depositing a target material comprising a component with a molecular weight of 90 u and 130 u and above, respectively. Naturally, deviations to lower molecular weights are also possible, for instance, for further components of an alloy or another target material. To name only a few examples, xenon and krypton might for instance be applied in the case of depositing gold (Au), silver (Ag), nickel (Ni), iron (Fe), cobalt (Co), tungsten (W) and copper (Cu).

Employing sputter deposition methods and sputter deposition systems according to embodiments of the present invention may, hence, be especially attractive whenever heavy target materials are involved in the sputter process, for instance, when a material has a low melting point, so that a reduction of a film temperature during the deposition might be desirable. Moreover, as the momentum of the scattered xenon or krypton ions is lower compared to that of argon ions so that an incorporation of the sputter gas into the deposited films may be reduced, the structure of the growing film can eventually be less distorted by the reflected atoms of the process gas. Eventually, an incorporation of the process gas might even be completely omittable.

In other words, traces of xenon or krypton might eventually be incorporated into films deposited according to some sputter deposition methods, which are dissolved in, for instance, gold/tin films or gathered in bubbles or voids of a solder junction, as for instance, gold/tin films sputtered according to embodiments of the present invention offer an excellent wetting and solderability on copper (Cu) lead frames. Hence, the situation might be different from that of employing argon, as the reflection of the sputter gas is in this case not as highly suppressed, leading to argon ions impinging on the wafer and being incorporated in significant amounts in the wafer or the deposited films.

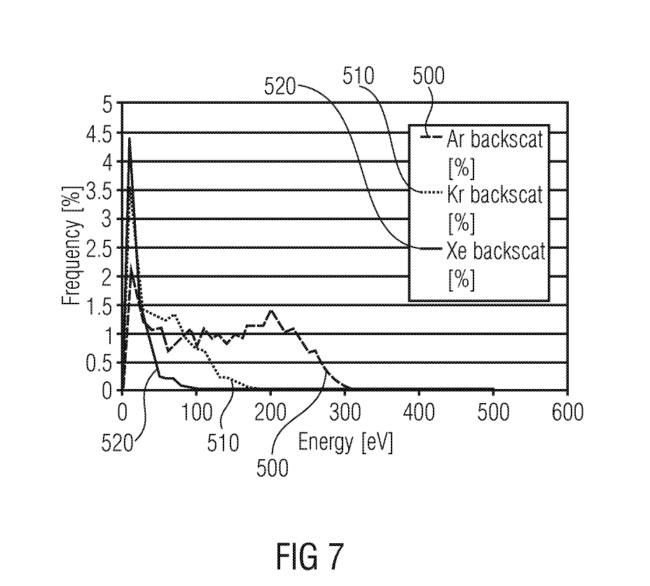

These estimations of the energy balance are also supported by SRIM simulations (SRIM=Stopping and Range of Ions in Matter) giving an energy distribution of reflected argon, krypton and xenon particles as well as the amount of reflected particles. FIG. 7 shows an example of such an energy distribution of reflected argon, krypton and xenon atoms in a collision with gold at an incident energy or primary energy of about 500 eV.

FIG. 7 shows three graphs 500, 510, 520 of SRIM simulations for argon (Ar, graph 500), krypton (Kr, graph 510) and xenon (Xe, graph 520). While the abscises of the graphs in FIG. 7 show the energy of the reflected ions, the ordinate shows a number of particles having the respective energy, which is also referred to as a frequency in percent.

While all three graphs 500, 510 and 520 have a peak in a range of less than about 50 eV indicating that a great number of particles comprise an energy of less than about 50 eV after a reflection, the graphs differs substantially from one another for higher energy values. Naturally, as the total number of reflected particles is 100%, due to the difference with respect to the higher energy levels, the peak height in the lower energy range below about 50 eV of the three graphs 500, 510, 520 is also different. The higher the peak is the less particles have an energy after the reflection of more than about 50 eV.

The most significant contribution above about 50 eV of the three graphs 500, 510, 520 shown in FIG. 7 have argon ions. Graph 500 shows a significant “high energy tail” in the energy range between approximately 50 eV and approximately 250 eV with intensities between about 0.5 and about 1.5%. This high energy tail of argon is a result of obtuse angled backscatter processes of the argon ions with respect to the gold atoms. With increasing atomic weight of the projectile or gas atoms, the high energy tail of the respective graphs is more and more reduced. Accordingly, the high energy tail of graph 510 for krypton is significantly reduced in terms of the energy. The distribution of reflected krypton ions having energies of approximately more than 130 eV is less than about 0.5%. In comparison, the distribution of reflected argon ions is less than about 0.5% only for energies of more than about 250 eV.

In comparison, however, the distribution of backscattered or reflected xenon ions comprises hardly any sign of a high energy tail. In the case of xenon, graph 520 shows that the distribution of backscattered xenon ions acquires values of less than about 0.5% for all energies above about 50 eV. Accordingly, the peak values of the backscattered xenon ions reaches values of almost 4.5%, whereas the peak value for argon is less than about 2.2%. In other words, the peak heights differ approximately by a factor of 2.

The measured wafer temperatures shown in FIG. 3 as well as the microstructures shown in FIGS. 4a to 4f of the deposited layers indicate that the deposition rate can be doubled by eliminating the heat source of the reflected projectile ions from the sputter gas by employing xenon or krypton as the sputter gas according to an embodiment of the present invention. This shows that this effect contributes a comparable amount of energy as the condensation and kinetic energy of the deposited metal atoms themselves.

Apart from the already described cold sputter deposition of gold/tin (AuSn) by the use of xenon or krypton as the process gas according to an embodiment of the present invention, other target materials can be used. Embodiments according to the present invention are for instance suitable for all products having sputtered gold/tin backsides for a diffusion soldering, like vertical LDMOS transistors (LDMOS=laterally double-diffused metal oxide semiconductor). Naturally, also other products with gold- or silver-based alloys for diffusion soldering or other metal films with a high atomic mass can be used in the context of embodiments according to the present invention.

While the foregoing has been particularly shown and described with reference to particular embodiments thereof, it will be understood by those skilled in the art that various other changes in the form and details may be made without departing from the spirit and scope thereof It is to be understood that various changes may be made in adapting to different embodiments without departing from the broader concept disclosed herein and comprehended by the claims that follow.

What is claimed is:

1. A sputter deposition method comprising:
providing a sputter gas comprising krypton or xenon; and
accelerating ions of a plasma of the sputter gas towards a target material.

2. The sputter deposition method according to claim 1, wherein the target material comprises an alloy of at least two chemical elements.

3. The sputter deposition method according to claim 1, wherein the target material comprises at least 1% of a mass of the target material of a chemical element with an atomic weight of at least 55 u, wherein u is the atomic mass unit.

4. The sputter deposition method according to claim 1, wherein the target material comprises at least 1% of a mass of the target material of a chemical element with an atomic weight of at least 90 u, wherein u is the atomic mass unit.

5. The sputter deposition method according to claim 1, wherein the target material comprises gold.

6. The sputter deposition method according to claim 5, wherein the target material further comprises tin.

7. The sputter deposition method according to claim 1, further comprising providing a first cold surface to the sputter gas with a temperature of less than 60 K and providing a second cold surface to the sputter gas with a temperature of more than 70 K.

8. The sputter deposition method according to claim 1, wherein accelerating the ions of the plasma comprises applying a voltage or an oscillating voltage to the target material.

9. A sputter deposition method using xenon or krypton as a sputter gas.

10. The sputter deposition method according to claim 9, wherein depositing a target material comprises depositing an alloy of at least two chemical elements.

11. The sputter deposition method according to claim 9, wherein depositing a target material comprises depositing at least 1% of a mass of the target material of a chemical element with an atomic weight of at least 55 u, wherein u is the atomic mass unit.

12. The sputter deposition method according to claim 9, wherein depositing a target material comprises depositing gold.

13. The sputter deposition method according to claim 12, wherein the target material further comprises tin.

14. A sputter deposition system comprising:
a process chamber;
a target material holder adapted to accommodate a target material inside the process chamber;
a substrate holder adapted to accommodate a substrate inside the process chamber;
a sputter gas inlet of the process chamber;
a gas source providing xenon or krypton;
a sputter gas supply system coupled to the sputter gas inlet and adapted to provide a gas from the gas source as a sputter gas; and
a pumping system coupled to the process chamber and adapted to pump the sputter gas out of the process chamber.

15. The sputter deposition system according to claim 14, wherein the gas source comprises a gas cylinder for xenon or krypton.

16. The sputter deposition system according to claim 14, wherein the pumping system comprises a cryo pump.

17. The sputter deposition system according to claim 16, wherein the cryo pump comprises at least two stages with a first cold surface and a second cold surface.

18. The sputter deposition system according to claim 14, further comprising a plasma generator.

19. The sputter deposition system according to claim 18, wherein the plasma generator comprises a voltage source adapted to provide a DC voltage or an AC voltage to the target material holder to generate a plasma.

20. The sputter deposition system according to claim 19, wherein the target holder comprises a magnet arranged such that electrons of the plasma move along spiral-like orbits at least in a vicinity of the target material holder.

21. A chip comprising:
a substrate comprising a film, wherein the film comprises xenon or krypton.

22. The chip according to claim 21, wherein the film is a thin film with a thickness of 50 μm or less.

23. The chip according to claim 21, wherein the film comprises xenon or krypton with a concentration of less than 10%.

24. The chip according to claim 21, wherein the film comprises traces of krypton or xenon with a concentration of at least 1 ppb.

25. The chip according to claim 21, wherein the film is on a backside of the substrate.
